(19) United States
(12) Patent Application Publication
(10) Pub. No.: US 2006/0076552 A1
(43) Pub. Date: Apr. 13, 2006

(54) Light emitting device and method for fabricating the same

(75) Inventors: Hiroji Ebe, Kawasaki (JP); Yoshiaki Nakata, Kawasaki (JP); Yasuhiko Arakawa, Kanagawa (JP)

Correspondence Address: ARMSTRONG, KRATZ, QUINTOS, HANSON & BROOKS, LLP, 1725 K STREET, NW, SUITE 1000, WASHINGTON, DC, 20006, US

(73) Assignees: FUJITSU LIMITED, Kawasaki (JP); THE UNIVERSITY OF TOKYO, Tokyo (JP)

(21) Appl. No.: 11/247,588

(22) Filed: Oct. 12, 2005

(30) Foreign Application Priority Data
Oct. 13, 2004 (JP) 2004-298779

(51) Int. Cl. H01L 31/109

(52) U.S. Cl. 257/14

(57) ABSTRACT

The light emitting device comprises a substrate 10 of a p-type semiconductor; an active layer 20 formed of a plurality of quantum dot layers 18 stacked, the quantum dot layers 18 having three-dimensional grown islands self-formed by S-K mode, respectively; and an n-type semiconductor layer 22 formed over the active layer. Because of the p-type semiconductor, over which the active layer 20 is formed on, and the n-type semiconductor, which is formed over the active layer 20, lower layer regions of the active layer 20, where good quantum dots 19 are formed are nearer to regions of the active layer 20, which are nearer to the p-type semiconductor. Accordingly, the radiation recombination between the holes and electrons takes place mainly in the regions where those of the quantum dots, which are of good quality. Thus, even when a number of the quantum dot layers 18 are stacked, good device characteristics can be obtained.

### CROSS-REFERENCE TO RELATED APPLICATION

This application is based upon and claims priority of Japanese Patent Application No. 2004-298779, filed on Oct. 13, 2004, the contents being incorporated herein by reference.

### BACKGROUND OF THE INVENTION

The present invention relates to a light emitting device and a method for fabricating the light emitting device, more specifically, a light emitting device including a quantum dot layer and a method for fabricating the light emitting device.

As a method for forming quantum dots, Stranski-Krastanaw mode (S-K mode) has been conventionally known.

The S-K mode is a mode that epitaxially growing semiconductor crystals grow two-dimensionally (in film) at the start of the growth and grow three-dimensionally when the elastic limit of the film is exceeded. A film whose lattice constant is different from that of a base material is epitaxially grown to thereby self-form quantum dots of several nanometer to several tens nanometer three-dimensional grown islands.

The S-K mode is much noted for being the mode which can easily self-form quantum dots.

A proposed light emitting device will be explained with reference to FIG. 9. FIG. 9 is a sectional view of the proposed light emitting device.

As illustrated in FIG. 9, an n-type semiconductor layer 114 is formed on, e.g., an n-type substrate 110. An active layer 120 of barrier layers 116 and quantum dot layer 118 alternately laid the later on the former is formed on the n-type semiconductor layer 114. Quantum dots 119 of three-dimensional grown island self-formed by the S-K mode are formed in the respective quantum dot layers 188. A p-type semiconductor layer 122 is formed on the active layer 120. An upper electrode 126 is formed on the p-type semiconductor layer 122. A lower electrode 128 is formed below the n-type substrate 110.

The proposed light emitting device is thus constituted.

Following references disclose the background art of the present invention.

[Patent Reference 1]
Specification of Japanese Patent Application Unexamined Publication No. 2002-237456

[Patent Reference 2]
Specification of Japanese Patent Application Unexamined Publication No. 2002-141531

However, in the proposed light emitting device, when a number of the quantum dot layers are stacked, the deviation of the emitted light wavelength from a required wavelength, etc. take place, and good device characteristics cannot be often obtained.

### SUMMARY OF THE INVENTION

An object of the present invention is to provide a light emitting device which can realize good device characteristics even when a number of the quantum dot layers are stacked, and a method for fabricating the light emitting device.

According to one aspect of the present invention, there is provided a light emitting device comprising: a substrate of a p-type semiconductor; an active layer formed over the substrate and formed of a plurality of quantum dot layers stacked, the quantum dot layers having three-dimensional grown islands self-formed by S-K mode, respectively; and an n-type semiconductor layer formed over the active layer.

According to another aspect of the present invention, there is provided a light emitting device comprising: a substrate; a p-type contact layer formed over the substrate; an active layer formed over the p-type contact layer and formed of a plurality of quantum dot layers stacked, the quantum dot layers having three-dimensional grown islands self-formed by S-K mode, respectively; and an n-type semiconductor layer formed over the active layer.

According to further another aspect of the present invention, there is provided a method for fabricating a light emitting device comprising the steps of: forming a p-type semiconductor layer over a substrate of a p-type semiconductor; forming over the p-type semiconductor layer an active layer formed of a plurality of quantum dot layers stacked, the quantum dot layers having three-dimensional grown islands self-formed by S-K mode, respectively; forming an n-type semiconductor layer over the active layer; and forming a lower electrode connected to the substrate and an upper electrode formed over the n-type semiconductor layer.

According to further another aspect of the present invention, there is provided a method for fabricating a light emitting device comprising the steps of: forming a p-type contact layer over a substrate: forming over the p-type contact layer an active layer of a plurality of quantum dot layers stacked, the quantum dot layers having three dimensional grown island formed by S-K mode, respectively; forming an n-type semiconductor layer over the active layer; and forming a lower electrode connected to the p-type contact layer and an upper electrode formed over the n-type semiconductor layer.

As described above, according to the present invention, the active layer formed of a number of the quantum dot layers stacked is formed on the p-type semiconductor, and the n-type semiconductor is formed on the active layer, whereby lower layer region of the active layer, where good quantum dots are formed are regions of the active layer, which are nearer to the p-type semiconductor. Accordingly, the radiation recombination between the holes and the electrons takes place mainly in the regions where those of the quantum dots, which are of good quality. Thus, according to the present invention, even when a number of the quantum dot layers are stacked, good device characteristics can be obtained.

### BRIEF DESCRIPTION OF THE DRAWINGS

FIGS. 1A and 1B are sectional views of the light emitting device according to a first embodiment of the present invention.

FIGS. 2A and 2B are sectional views of the light emitting device according to the first embodiment of the present invention in the steps of the method for fabricating the light emitting device, which illustrate the method (Part 1).

FIGS. 3A and 3B are sectional views of the light emitting device according to the first embodiment of the present invention in the steps of the method for fabricating the light emitting device, which illustrate the method (Part 2).

FIG. 4 is sectional views of the light emitting device according to the first embodiment of the present invention in the steps of the method for fabricating the light emitting device, which illustrate the method (Part 3).

FIG. 5 is a sectional view of the light emitting device according to one modification of the first embodiment of the present invention.

FIGS. 6A and 6B are sectional views of the light emitting device according to a second embodiment of the present invention.

FIGS. 7A and 7B are sectional views of the light emitting device according to the second embodiment of the present invention in the steps of the method for fabricating the light emitting device, which illustrate the method (Part 1).

FIG. 8 is a sectional view of the light emitting device according to the second embodiment of the present invention in the steps of the method for fabricating the light emitting device, which illustrates the method (Part 2).

FIG. 9 is a sectional view of the proposed light emitting device.

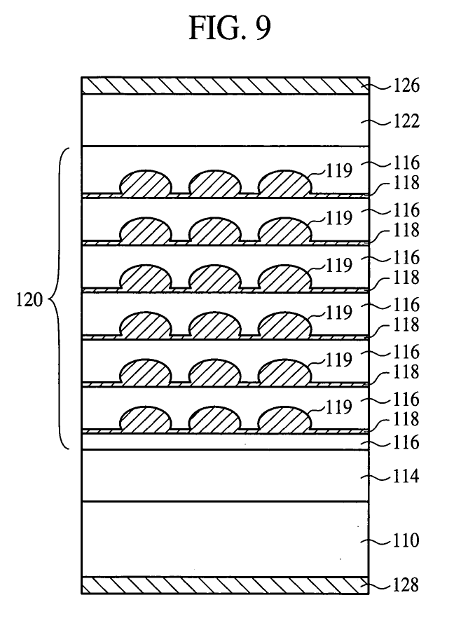

### DETAILED DESCRIPTION OF THE INVENTION

The inventors of the present application have made earnest studies of the reason why the proposed light emitting device cannot have good device characteristics.

As a number of quantum layers forming an active layer are stacked, good quantum dots can be formed on lower one of the quantum dot layers, but as the quantum dot layers are higher, good quantum dots cannot be formed. Good quantum dots being unable to be formed as the quantum dot layers are higher will be due to that as the quantum dot layers are higher, larger crystal strains are formed in the quantum dot layers.

The proposed light emitting device is operated by the radiation recombination in the quantum dots between electrons supplied from the side of the n-type semiconductor layer and holes supplied from the side of the p-type semiconductor layer. The mobility of the hole is smaller than by about one digit, and the radiation recombination between the electrons and the holes takes place mainly in the quantum dots present in regions of the active layer, which are nearer to the p-type semiconductor layer. The regions of the active layer, which are nearer to the p-type semiconductor layer are upper regions of the active layer, which are regions where, as described above, quantum dots of poor quality are formed. Thus, in the proposed light emitting device including a number of the quantum dot layer stacked, the radiation recombination between the electrons and holes takes place mainly in the quantum dots of poor quality. Resultantly, the proposed light emitting device often cannot have good device characteristics.

The inventors of the present application have made earnest studies and had the idea that even when a number of the quantum dot layer are stacked, the active layer is formed on a p-type semiconductor, and an n-type semiconductor is formed on the active layer, whereby good device characteristics can be obtained. The active layer is formed on the p-type semiconductor, and the n-type semiconductor layer is formed on the active layer, whereby lower regions of the active layer are regions nearer to the p-type semiconductor. As described above, the lower regions of the active layer are regions, where quantum dots of good quality are formed. The radiation recombination between the electrons and the holes takes pace mainly in regions of the active layer nearer to the p-type semiconductor. Accordingly, the radiation recombination between the electrons and the holes takes place in those of the quantum dots, which are of good quality. Thus, according to embodiments of the present invention which will be described below, even when a number of quantum dot layers are stacked, good device characteristics can be obtained.

### A First Embodiment

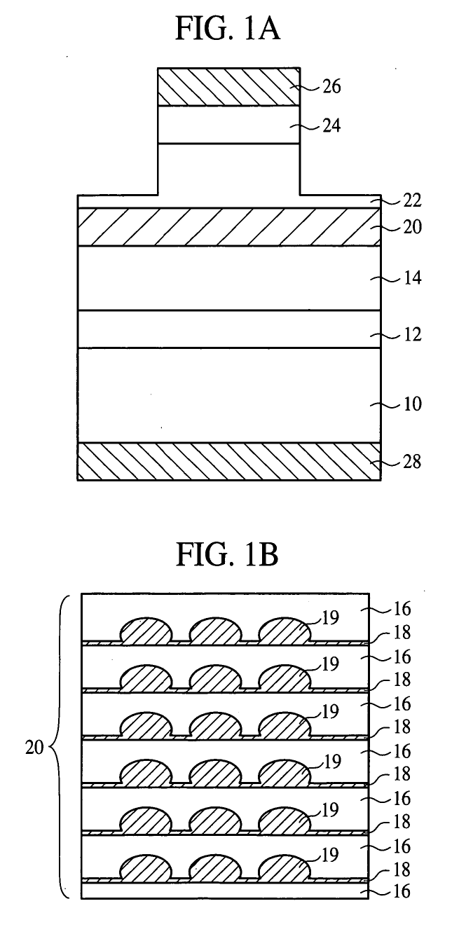

Next, the light emitting device according to a first embodiment of the present invention and the method for fabricating the light emitting device will be explained with reference to FIGS. 1A to 4. FIGS. 1A and 1B are sectional views of the light emitting device according to the present embodiment. FIG. 1A is a sectional views illustrating the general structure of the light emitting device according to the present embodiment, and FIG. 1B is a sectional view of the structure of the active layer.

As illustrated in FIGS. 1A and 1B, a p-type buffer layer 12 is formed on a p-type substrate 10. The p-type substrate is, e.g., a p-type InP substrate. The p-type buffer layer 12 is, e.g., a p-type InP layer. The concentration of the p-type dopant impurity implanted in the substrate is, e.g., about 1×10¹⁸-1×10¹⁹ cm⁻³. The concentration of the p-type dopant impurity implanted in the buffer layer 12 is, e.g., about 1×10¹⁸ cm⁻³.

A p-type semiconductor layer 14 is formed on the p-type buffer layer 12. The p-type semiconductor layer 14 functions as, e.g., a lower clad layer. The p-type semiconductor layer 14 is, e.g., a p-type InP layer. The concentration of the p-type dopant impurity implanted in the semiconductor layer 14 is, e.g., about 1×10¹⁷-6×10¹⁷ cm⁻³. The concentration of the p-type dopant impurity implanted in the p-type semiconductor layer 14 is set relatively low, because when the concentration of the impurity is too high, the light loss become large, and required device characteristics cannot be obtained.

An active layer 20 of barrier layers 16 and quantum dot layer 18 stacked alternately the latter on the former is formed on the p-type semiconductor layer 14.

The barrier layer 16 is, e.g., an undoped In_{X}(Al_{Y}Ga_{1-Y})_{1-X}As layer. The composition of the In_{X}(Al_{Y}Ga_{1-Y})_{1-X}As layer is set at, e.g., X=0.53 and Y=0.5.

The barrier layer 16 is formed here of In_{X}(Al_{Y}Ga_{1-Y})_{1-X}As, but the material of the barrier layer 16 is not essentially In_{X}(Al_{Y}Ga_{1-Y})_{1-X}As. For example, undoped In_{X}Ga_{1-X}As_{Y}P_{1-Y} or others may be used as the material of the barrier layer 16.

The quantum dot layer 18 is, e.g., an undoped In_{X}Ga_{1-X}As layer. A plurality of quantum dots 19 are formed in the quantum dot layers 18. The quantum dots 19 are formed of three-dimensional grown islands self-formed by the S-K mode. The thickness of the quantum dot layers 18 is, e.g., about 1-6 monolayers.

The number of the quantum dot layers 18 forming the active layer 20 is, e.g., about 5-60 layers. As described above, in the active layer 20 formed of a number of the quantum dot layers 18 stacked, the quality of the quantum dots 19 tend to be degraded in the higher quantum dot layers 18. Accordingly, the light emitting device of a larger number of the quantum dot layers 18 tends to have the device characteristics more conspicuously improved. Thus, the present invention is effective for the light emitting device including 5 or more quantum dot layers. The present invention is further effective to the light emitting device including 10 or more quantum dot layers. The present invention is more further effective for the light emitting device including 15 or more quantum dot layers.

An n-type semiconductor layer 22 is formed on the active layer 20. The n-type semiconductor layer 22 functions as, e.g., an upper clad layer. The n-type semiconductor layer 22 is, e.g., an n-type InP layer. The concentration of the n-type dopant implanted in the semiconductor layer 22 is, e.g., about 1×10¹⁷-5×10¹⁷ cm⁻³.

An n-type contact layer 24 is formed on the n-type semiconductor layer 22. The n-type contact layer 24 is, e.g., an n-type InP layer. The concentration of the n-type dopant impurity implanted in the contact layer 24 is, e.g., about 1×10¹⁹ cm⁻³.

The upper part of the clad layer 22 and the contact layer 24 are formed generally in a mesa.

An upper electrode 26 of metal is formed on the contact layer 24.

A lower electrode 28 of metal is formed on the undersurface of the substrate 10.

Thus, the light emitting device according to the present embodiment is constituted.

The light emitting device according to the present embodiment is characterized mainly in that the active layer 20 formed of a number of quantum dot layers 18 stacked is formed on the p-type semiconductor layers 10, 12, 14, and the n-type semiconductor layers 22, 24 are formed on the active layer 20.

In the proposed light emitting device, as described above, on the n-type semiconductor layer, the active layer of a number of the quantum dot layer is formed, and the p-type semiconductor layer is formed on the active layer. As described above, because of the mobility of holes which is smaller by one digit than that of electrons, the radiation recombination takes place in regions of the active layer nearer to the p-type semiconductor, i.e., in upper layer regions of the active layer. The upper layer regions of the active layer are regions where the quantum dots of poor quality are formed, and the proposed light emitting device cannot have good device characteristics.

In the present embodiment, however, the active layer 20 of a number of the quantum dot layers 18 is formed on the p-type semiconductor 10, 12, 14, and the n-type semiconductor 22, 24 are formed on the active layer 20. According to the present embodiment, wherein the active layer 20 is formed on the p-type semiconductor layers 10, 12, 14, and the n-type semiconductor layers 22, 24 are formed on the active layer 20, the lower layer regions, which are regions of the active layer 20, where the quantum dots 19 have good quality are nearer to the p-type semiconductor 10, 12, 14 of the active layer 20. The radiation recombination between the holes and the electrons take place mainly in the regions where the quantum dots 19 of good quality are formed. Thus, according to the present embodiment, even when a number of the quantum dot layers are stacked, good device characteristics can be obtained.

(The Method for Fabricating the Light Emitting Device)

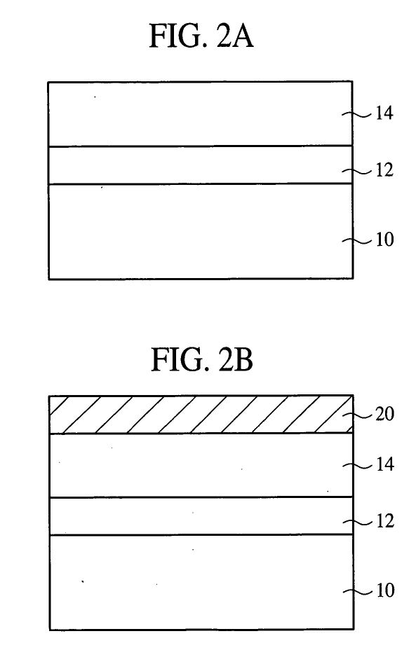

Next, the method for fabricating the light emitting device according to the present embodiment will be explained with reference to FIGS. 2A to 4. FIGS. 2A to 4 are sectional views of the light emitting device according to the present embodiment in the steps of the method for fabricating the light emitting device, which illustrate the method.

First, as illustrated in FIG. 2A, the p-type substrate 10 is prepared. As the p-type substrate 10, a p-type InP substrate, for example is prepared. The concentration of the p-type dopant impurity to be implanted in the substrate 10 is about, e.g., 1×10¹⁸-1×10¹⁹ cm⁻³.

Next, the p-type buffer layer 12 is formed on the entire surface of the substrate 10 by, e.g., MBE (Molecular Beam Epitaxy). As the p-type buffer layer 12, a p-type InP layer, for example, is formed. The concentration of the p-type dopant impurity to be implanted into the buffer layer 12 is, e.g., about 1×10¹⁸ cm⁻³. The temperature inside the film forming chamber for forming the buffer layer 12 is, e.g., about 550-650° C. The thickness of the buffer layer 12 is, e.g., about 100-1000 nm.

Next, the p-type semiconductor layer 14 is formed on the entire surface by, e.g., MBE. As described above, the p-type semiconductor layer 14 functions as, e.g., the lower clad layer. As the p-type semiconductor layer 14, a p-type InP layer is formed. The concentration of the p-type dopant impurity to be implanted into the semiconductor layer 14 is, e.g., about 5×10¹⁷ cm⁻³. The thickness of the p-type semiconductor layer 14 is, e.g., about 3 μm. The temperature inside the film forming chamber for forming the p-type semiconductor layer 14 is, e.g., about 550-650° C.

Then, as illustrated in FIG. 2B, the active layer 20 is formed on the lower clad layer 14.

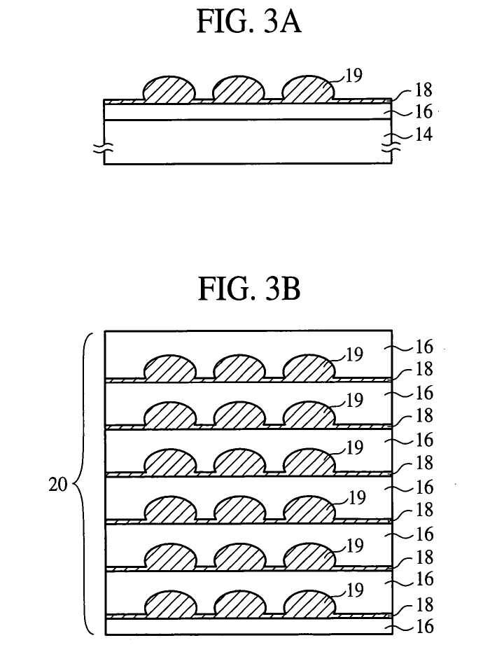

The method for forming the active layer will be explained here with reference to FIGS. 3A and 3B.

First, as illustrated in FIG. 3A, the barrier layer 16 is formed on the entire surface of the p-type semiconductor layer 14 by, e.g., MBE. As the barrier layer 16, an undoped In_{X}(Al_{Y}Ga_{1-Y})_{1-X}As layer, for example is formed. In the composition of the In_{X}(Al_{Y}Ga_{1-Y})_{1-X}As, for example, X=0.53, and Y=0.5. The temperature inside the film forming chamber for forming the barrier layer 16 is, e.g., about 550-650° C. The thickness of the barrier layer 16 is, e.g., about 30 nm.

Then, as illustrated in FIG. 3B, the quantum dot layer 18 is formed on the entire surface of the barrier layer 16 by, e.g., MBE. As the quantum dot layer 18, undoped In_{X}Ga_{1-X}As layer, for example is formed. In the composition X of the In_{X}Ga_{1-X}As is, e.g., 0.8-1.0. The thickness of the quantum dot layer 18 is, e.g., about 1-6 monolayers. The temperature inside the film forming chamber for forming the quantum dot layer 18 is, e.g., 450-550° C. Because of the difference in the lattice constant between the material of the quantum dot layer 18 and the barrier layer 16, the quantum dots 19 are self-formed in the quantum dot layer 18 by the S-K mode.

Hereafter, the barrier layer 16 and the quantum dot layer 18 are alternately formed. Thus, as illustrated in FIG. 3B, the active layer 20 of the barrier layers 16 and the quantum dot layers 18 stacked is formed. The number of the quantum dot layers is, e.g., about 5-60 layers.

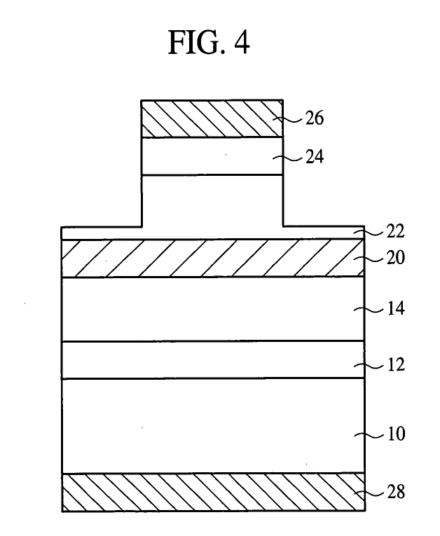

Then, as illustrated in FIG. 4, the n-type semiconductor layer 22 is formed on the entire surface by, e.g., MBE. As described above, the n-type semiconductor layer 22 functions as, the upper clad layer. As the n-type semiconductor layer 22, an n-type InP layer, for example, is formed. The concentration of the n-type dopant impurity to be implanted into the n-type semiconductor layer 22 is, e.g., about 1×10¹⁷-5×10¹⁷ cm⁻³. The thickness of the n-type semiconductor layer 22 is, e.g., about 3 μm.

Then, the n-type contact layer 24 is formed on the entire surface by, e.g., MBE. As the n-type contact layer 24, an n-type InP layer, for example is formed. The concentration of the n-type dopant impurity to be implanted into the contact layer 24 is, e.g., 1×10¹⁹ cm⁻³. The thickness of the contact layer 24 is, e.g., about 0.5 μm.

In the above, the respective layers are formed by MBE. However, the respective layers are not formed essentially by MBE and may be formed by, e.g., MOCVD (Metal-Organic Chemical Vapor Deposition). Conditions for forming the respective layers by MOCVD are as exemplified below.

The temperature inside the film forming chamber for forming the buffer layer 12, the p-type semiconductor layer 14, the barrier layers 16, the n-type semiconductor layer 22 and the contact layer 24 is, e.g., 550-700° C. The temperature inside the film forming chamber for forming the quantum dot layers 18 is, e.g., 450-550° C.

The respective layers may be thus formed by MOCVD.

Next, the contact layer 24 and the clad layer 22 are etched generally into a mesa.

Next, the upper electrode 26 of metal is formed on the contact layer 24 by, e.g., sputtering.

The lower electrode 28 of metal is formed on the underside of the substrate 10 by, e.g., sputtering.

Thus, the light emitting device according to the present embodiment is fabricated.

(A Modification)

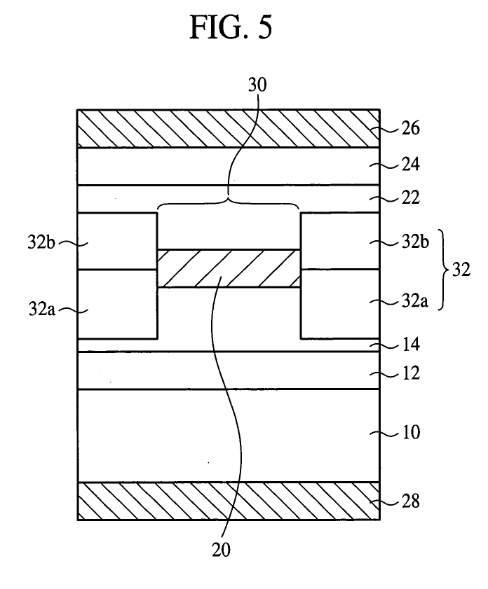

Next, a modification of the light emitting device according to the present embodiment will be explained with reference to FIG. 5. FIG. 5 is a sectional view of the light emitting device according to the present modification.

In the light emitting device according to the present modification, the p-type semiconductor layer 14, the active layer 20 and the n-type semiconductor layer 22 are formed generally in a mesa, and the buried layer 32 is formed on both side of the mesa 30 of the p-type semiconductor layer 14, the active layer 20 and the n-type semiconductor layer 22.

As illustrated in FIG. 5, the p-type semiconductor layer 14, the active layer 20 and the n-type semiconductor layer 22 are formed generally in a mesa.

A buried layer 32 of, e.g., an n-InP layer 32a and a p-type InP layer 32b is formed on both side of the mesa 30 formed of the p-type semiconductor layer 14, the active layer 20 and the n-type semiconductor layer 22. The buried layer 32 functions as, e.g., a current restricting layer.

As described above, it is possible that the n-type semiconductor layer 14, the active layer 20 and the p-type semiconductor layer 22 are formed generally in a mesa, and the buried layer 32 is formed on both sides of the mesa 30.

### A Second Embodiment

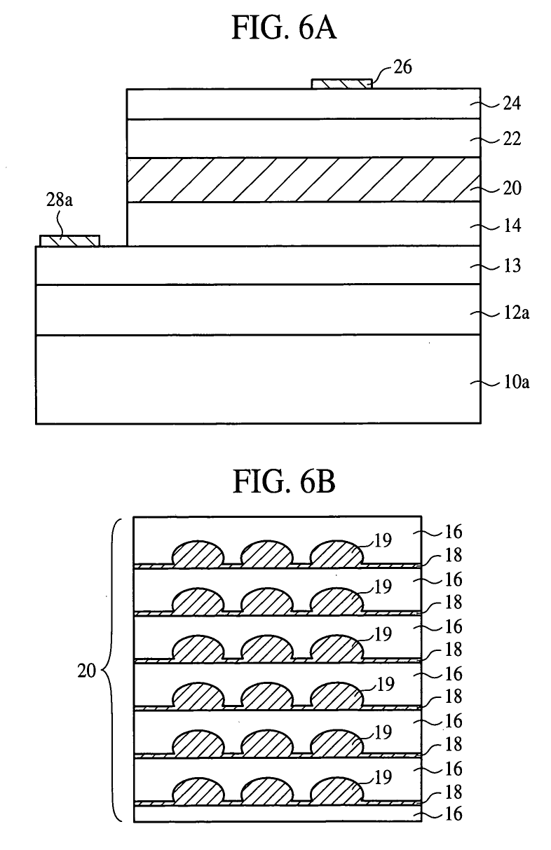

The light emitting device according to a second embodiment of the present invention and the method for fabricating the light emitting device will be explained with reference to FIGS. 6A to 8. FIGS. 6A and 6B are sectional views of the light emitting device according to the present embodiment. FIG. 6A is a sectional view of the light emitting device according to the present embodiment, which illustrates a general structure thereof, and FIG. 6B is a sectional view of the light emitting device according to the present embodiment, which illustrates the active layer. The same members of the present embodiment as those of the light emitting device according to the first embodiment and the method for fabricating the light emitting device illustrated in FIGS. 1A to 5 are represented by the same reference numbers not to repeat or to simplify their explanation.

(The Light Emitting Device)

First, the light emitting device according to the present embodiment will be explained with reference to FIGS. 6A and 6B.

The light emitting device according to the present embodiment is characterized mainly in that a contact layer 13 is formed between a buffer layer 12a and a p-type semiconductor layer 14, and a lower electrode 28a is connected onto the p-type contact layer 13.

As illustrated in FIG. 6A, the buffer layer 12a is formed on a substrate 10a. As the substrate 10a, an InP substrate, for example, is used. the conduction type of the substrate 10a is p-type or i-type (intrinsic semiconductor). In the present embodiment, the concentration of the p-type impurity implanted in the substrate 10a may not be high. As the buffer layer 12a, an InP layer, for example, is used. The conduction type of the buffer layer 12a is p-type or i-type.

A p-type contact layer 13 is formed on the buffer layer 12a. As the p-type contact layer 13, a p-type InP layer, for example, is used. The concentration of the p-type dopant impurity implanted in the contact layer 13 is, e.g., about 1×10¹⁹ cm⁻³, which is relatively higher. The concentration of the p-type dopant impurity implanted in the contact layer 13 is set relatively higher so that the contact layer 13 has low electric resistance.

A p-type semiconductor layer 14 is formed on the p-type contact layer 13, The concentration of the p-type dopant impurity implanted in the semiconductor layer 14 is, e.g., about 1×10¹⁷-6×10¹⁷ cm⁻³, which is the same as in the light emitting device according to the first embodiment. The impurity concentration of the p-type dopant impurity implanted in the contact layer 14 is set lower than the impurity concentration of the p-type contact layer 13, because when the impurity concentration is too high, the light loss becomes too large to obtain required device characteristics.

On the p-type semiconductor layer 14, an active layer 20, an n-type semiconductor layer 22, an n-type contact layer 24 and an upper electrode 26 are formed sequentially the latter on the former.

A lower electrode 28a is formed on the p-type contact layer 13.

The p-type contact layer 13 may be thus formed below the p-type semiconductor layer 14.

In the light emitting device according to the first embodiment, as the substrate 10, the substrate 10 with the p-type dopant impurity heavily implanted is used. The substrate 10 with the p-type dopant impurity heavily implanted is used so that the electric resistance in the interface between the p-type substrate 10 and the lower electrode 28 is decreased. The heavy implantation of the p-type dopant impurity in the substrate 10, however, often does not sufficiently activate the dopant impurity implanted in the substrate, and the electric resistance in the p-type substrate 10 cannot be set sufficiently low. In such case, because of the high electric resistance in the p-type substrate 10, required device characteristics cannot be obtained.

In the present embodiment, however, because of the contact layer 13 with the p-type impurity heavily implanted, which is formed below the p-type semiconductor layer 14, sufficiently low electric resistance can be obtained in the interface between the p-type contact layer 13 and the lower electrode 28a. Furthermore, because of the lower electrode 28a connected to the p-type contact layer 13, the electric resistance between the lower electrode 28a and the p-type semiconductor layer 14 can be set low even when the electric resistance between the buffer layer 12a below the p-type contact layer 13 and the substrate 10a. Thus, according to the preset embodiment, good device characteristics can be obtained even when the electric resistance of the substrate 10a is high.

[The Method for Fabricating the Light Emitting Device]

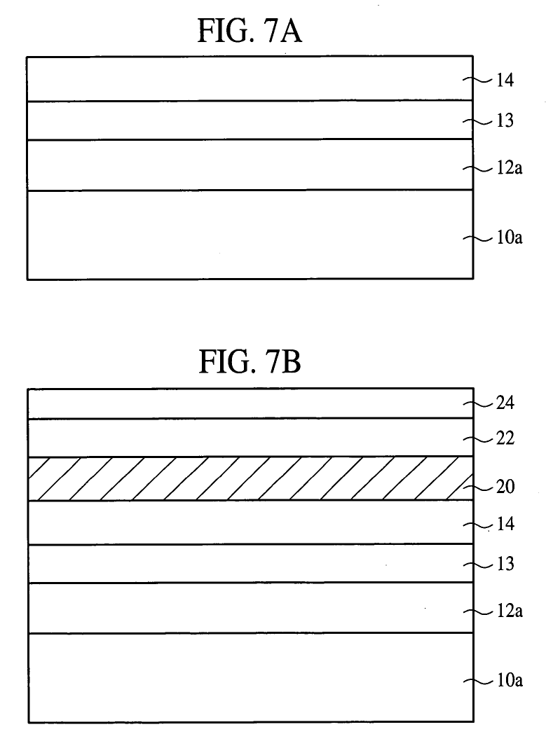

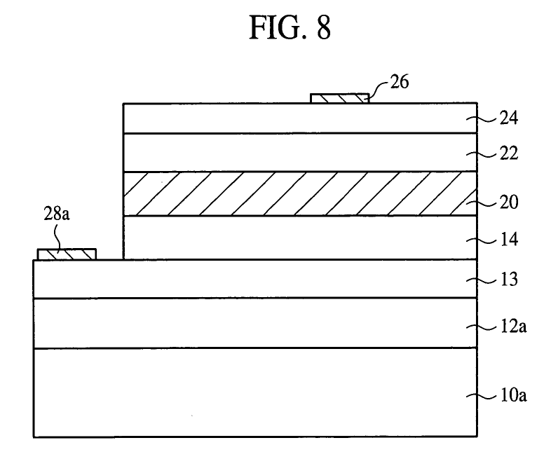

Next, the method for fabricating the light emitting device according to the present embodiment will be explained with reference to FIGS. 7A to 8. FIGS. 7A to 8 are sectional views of the light emitting device according to the present embodiment in the steps of the method for fabricating the light emitting device, which illustrate the method.

First, as illustrated in FIG. 7A, the substrate 10a is prepared. The substrate 10a is, e.g., an InP substrate. The conduction type of the substrate 10a is p-type or i-type.

Next, the buffer layer 12a is formed on the substrate 10a by, e.g., MBE. The conduction type of the buffer layer 12a is p-type or i-type.

Then, the p-type contact layer 13 is formed on the buffer layer 12a by, e.g., MBE. The p-type contact layer 13 is, e.g., a p-type InP layer. The concentration of the p-type dopant impurity to be implanted into the contact layer 13 is, e.g., about 1×10¹⁹ cm⁻³. The temperature is inside the film forming chamber for forming the contact layer 13 is, e.g., about 550-650° C. The thickness of the contact layer 13 is, e.g., about 0.1-0.5 μm.

Hereafter, in the same way as in the method for fabricating the light emitting device according to the first embodiment, the p-type semiconductor layer 14, the active layer 20, the n-type semiconductor layer 22 and the n-type contact layer 24 are sequentially formed (see FIG. 7B).

Next, the n-type contact layer 24, the n-type semiconductor layer 22, the active layer 20 and the p-type semiconductor layer 14 are etched into a mesa.

Next, the upper electrode 26 is formed on the n-type contact layer 24 by, e.g., sputtering. The lower electrode 28a is formed on the p-type contact layer 13.

The light emitting device according to the present embodiment is thus fabricated.

### Modified Embodiments

The present invention is not limited to the above-described embodiments and can cover other various modifications.

For example, in the above-described embodiments, InP-based materials are used as the materials of the substrate and the respective layers, but the materials of the substrate and the respective layers are not limited to the InP-based materials. The materials of the substrate and the respective layers may be suitably set.

For example, GaAs-based materials may be used as the materials of the substrate and the respective layers. When GaAs-based materials are used as the materials of the substrate and the respective layers, the structure may be as exemplified below.

That is, the p-type substrate 10 is, e.g., a p-type GaAs substrate. The concentration of the p-type dopant impurity implanted in the substrate 10 is, e.g., about 1×10¹⁸-1×10¹⁹ cm⁻³.

The p-type buffer layer 12 is, e.g., a p-type GaAs layer. The concentration of the p-type dopant impurity implanted in the buffer layer 12 is, e.g., about 1×10¹⁸ cm⁻³.

The p-type contact layer 12 is, e.g., a p-type GaAs layer. The concentration of the p-type dopant impurity implanted in the contact layer 13 is, e.g., about 1×10¹⁹ cm⁻³.

The p-type semiconductor layer 14 is, e.g., a p-type Al_{X}Ga_{1-X}As layer. The composition ratio X of the Al_{X}Ga_{1-X}As layer is, e.g., 0.3-0.8. The concentration of the p-type dopant impurity implanted in the p-type semiconductor layer 14 is, e.g., about 1×10¹⁷-6×10¹⁷ cm⁻³.

The buffer layer 16 is, e.g., an undoped GaAs layer.

The quantum dot layers 18 are, e.g., undoped In_{X}Ga_{1-X}As layers.

The n-type semiconductor layer 22 is, e.g., an n-type Al_{X}Ga_{1-X}As layer. The composition ratio X of the Al_{X}Ga_{1-X}As layer is, e.g., about 0.3-0.8. The concentration of the n-type dopant impurity implanted in the semiconductor layer 22 is, e.g., about 1×10¹⁷-5×10¹⁷ cm⁻³.

The n-type contact layer 24 is, e.g., an n-type GaAs layer. The concentration of the n-type dopant impurity implanted in the contact layer 24 is, e.g., about 1×10¹⁹ cm⁻³.

GaAs-based materials may be thus used as the materials of the substrate and the respective layers.

In the second embodiment, the conduction type of the substrate 10a is p-type or i-type. However, in the second embodiment, the conduction type of the substrate 10a may be n-type. In the second embodiment, the conduction type of the buffer layer 12a is p-type or i-type. However, in the second embodiment, the conduction type of the buffer layer 12a may be n-type. Because the conduction type of the contact layer 13 connected to the lower electrode 28a is p-type, the substrate 10a and the buffer layer 12a below the contact layer 13 being n-type makes no special problem.

The general structure of the light emitting device the principle of the present invention is applicable to is not limited to the light emitting device described above. The principle of the present invention is applicable to light emitting devices of any other structure.

The principle of the present invention is applicable to all the light emitting devices, such as light amplifiers, laser diodes, LED, etc.

What is claimed is:

1. A light emitting device comprising:
a substrate of a p-type semiconductor;
an active layer formed over the substrate and formed of a plurality of quantum dot layers stacked, the quantum dot layers having three-dimensional grown islands self-formed by S-K mode, respectively; and
an n-type semiconductor layer formed over the active layer.

2. A light emitting device according to claim 1, further comprising
a p-type semiconductor layer formed between the substrate and the active layer, the p-type semiconductor layer having an impurity concentration lower than that of the substrate.

3. A light emitting device according to claim 1, further comprising:
a first electrode connected to the substrate; and
a second electrode formed over the n-type semiconductor layer.

4. A light emitting device comprising:
a substrate;
a p-type contact layer formed over the substrate;
an active layer formed over the p-type contact layer and formed of a plurality of quantum dot layers stacked, the quantum dot layers having three-dimensional grown islands self-formed by S-K mode, respectively; and
an n-type semiconductor layer formed over the active layer.

5. A light emitting device according to claim 4, further comprising
a p-type semiconductor layer formed between the p-type contact layer and the active layer, the p-type semiconductor layer having an impurity concentration lower than that of the p-type contact layer.

6. A light emitting device according to claim 4, further comprising:
a first electrode connected to the p-type contact layer; and
a second electrode formed over the n-type semiconductor layer.

7. A light emitting device according to claim 1, wherein
the quantum dot layers are stacked on each other with a barrier layer formed therebetween.

8. A light emitting device according to claim 4, wherein
the quantum dot layers are stacked on each other with a barrier layer formed therebetween.

9. A light emitting device according to claim 1, wherein
the active layer includes ten or more quantum dot layers.

10. A light emitting device according to claim 4, wherein
the active layer includes ten or more quantum dot layers.

11. A light emitting device according to claim 1, wherein
the substrate is formed of InP or GaAs.

12. A light emitting device according to claim 4, wherein
the substrate is formed of InP or GaAs.

13. A method for fabricating a light emitting device comprising the steps of:
forming a p-type semiconductor layer over a substrate of a p-type semiconductor;
forming over the p-type semiconductor layer an active layer formed of a plurality of quantum dot layers stacked, the quantum dot layers having three-dimensional grown islands self-formed by S-K mode, respectively;
forming an n-type semiconductor layer over the active layer; and
forming a lower electrode connected to the substrate and an upper electrode formed over the n-type semiconductor layer.

14. A method for fabricating a light emitting device comprising the steps of:
forming a p-type contact layer over a substrate:
forming over the p-type contact layer an active layer of a plurality of quantum dot layers stacked, the quantum dot layers having three dimensional grown island formed by S-K mode, respectively;
forming an n-type semiconductor layer over the active layer; and
forming a lower electrode connected to the p-type contact layer and an upper electrode formed over the n-type semiconductor layer.
